(19) United States
(12) Patent Application Publication
(10) Pub. No.: US 2018/0278128 A1
(43) Pub. Date: Sep. 27, 2018

(54) HEATSINK AND MOTOR DRIVING DEVICE

(71) Applicant: FANUC CORPORATION, Yamanashi (JP)

(72) Inventors: Kenichi Okuaki, Yamanashi-ken (JP); Kazuhiro Yamamoto, Yamanashi-ken (JP)

(73) Assignee: FANUC CORPORATION, Yamanashi (JP)

(21) Appl. No.: 15/928,147

(22) Filed: Mar. 22, 2018

(30) Foreign Application Priority Data
Mar. 24, 2017 (JP) 2017-058775

(51) Int. Cl. H02K 9/22; H05K 7/20

(52) U.S. Cl. CPC H02K 9/22; H05K 7/20909; H05K 7/20181; H05K 7/2039

(57) ABSTRACT

A heatsink includes: a heatsink main body; a flange portion formed on the heatsink main body; and a filter plate detachably attached to an end portion on an inlet side of the heatsink main body. In the state where the filter plate is attached to the end portion on the inlet side of the heatsink main body, an outer shape of the filter plate is larger than an outer shape of the end portion on the inlet side of the heatsink main body. An insertion hole formed in the flange portion allows insertion of the filter plate to be inserted. A flange is formed on the filter plate and at an end portion on a side opposite to a forefront end of the filter plate in an insertion direction.

### CROSS-REFERENCE TO RELATED APPLICATION

This application is based upon and claims the benefit of priority from Japanese Patent Application No. 2017-058775 filed on Mar. 24, 2017, the contents of which are incorporated herein by reference.

### BACKGROUND OF THE INVENTION

### Field of the Invention

The present invention relates to a heatsink that cools an electronic part, and a motor driving device that includes the heatsink.

### Description of the Related Art

Conventionally, heatsinks are used to cool electronic parts. However, when a heatsink is used in a dusty or cutting-fluid-scattering environment, the dust or the cutting fluid is adhered to an end portion on an inlet side of the heatsink, causing clogging. Therefore, a fluid flow becomes worse, and cooling performance deteriorates.

Hence, Japanese Laid-Open Patent Publication No. 2010-056385 discloses providing at an end portion on an inlet side of a heatsink a filter formed in the same shape in cross section as the end portion of the heatsink on the inlet side. Japanese Laid-Open Patent Publication No. 2010-056385 discloses using a guide rail and disposing the filter between the end portion on the inlet side of the heatsink and a fan.

### SUMMARY OF THE INVENTION

Japanese Laid-Open Patent Publication No. 2010-056385 has a problem that the guide rail is used and the filter (referred to as a filter plate below) is disposed between the end portion on the inlet side of the heatsink and the fan, and therefore the structure for positioning the filter becomes complicated and costly. Further, the cross-sectional shape of the end portion of the heatsink and the cross-sectional shape of the filter are the same. Therefore, only a fluid whose amount corresponds to the cross-sectional shape of the end portion of the heatsink flows in the heatsink. Thus, improvement of the cooling performance cannot be expected.

It is therefore an object of the present invention to provide a heatsink and a motor driving device that adopt a simple structure to position a filter plate, and improve cooling performance.

A first aspect of the present invention is a heatsink configured to cool an electronic part, and includes: a heatsink main body including a plurality of fins; a flange portion formed on the heatsink main body to install the heatsink with the electronic part mounted thereon; and a filter plate detachably attached to an end portion on an inlet side of the heatsink main body, and in a state where the filter plate is attached to the end portion on the inlet side of the heatsink main body, an outer shape of the filter plate is larger than an outer shape of the end portion on the inlet side of the heatsink main body on a plane perpendicular to a flow direction of a fluid in the heatsink main body, an insertion hole formed in the flange portion allows the filter plate to be inserted to attach the filter plate from a side of the flange portion to the end portion on the inlet side of the heatsink main body, and a flange is formed on the filter plate at an end portion on a side opposite to a forefront end of the filter plate in an insertion direction of the filter plate into the insertion hole for positioning the filter plate with respect to the heatsink main body.

A second aspect of the present invention is a motor driving device configured to drive a motor, and includes: the heatsink according to the first aspect; and the electronic part.

According to the present invention, the simple configuration can easily position the filter plate with respect to the end portion on the inlet side of the heatsink main body. Further, it is possible to increase the amount of the fluid flowing in the heatsink main body, and improve the cooling performance.

The above and other objects features and advantages of the present invention will become more apparent from the following description when taken in conjunction with the accompanying drawings in which a preferred embodiment of the present invention is shown by way of illustrative example.

### BRIEF DESCRIPTION OF THE DRAWINGS

FIG. 1 is an external perspective view showing a configuration of a control panel and a motor driving device according to an embodiment;

FIG. 2 is a partial cross-sectional view along a line II-II in FIG. 1;

FIG. 3A is an external perspective view of a heatsink shown in FIG. 1 in a state before a filter plate is attached to an inlet side of a heatsink main body;

FIG. 3B is an external perspective view of the heatsink shown in FIG. 1 in a state after the filter plate is attached to the inlet side of the heatsink main body;

FIG. 4 is a view of the heatsink main body and the filter plate, showing flows of a fluid flowing in the heatsink main body shown in FIG. 1, viewed from front;

FIG. 5 is a view for explaining attachment of the filter plate to an end portion on the inlet side of the heatsink main body;

FIG. 6A is a view showing an end portion on a lower side (inlet side) of the heatsink main body from below;

FIG. 6B is a view showing the filter plate from below;

FIG. 6C is a view showing the filter plate attached to the end portion on the inlet side of the end portion of the heatsink main body from below;

FIG. 7 is a perspective view showing a configuration of the filter plate according to a first modification;

FIG. 8 is a view showing a configuration of a fixing member according to a third modification;

FIG. 9 is a cross-sectional view along a line IX-IX in

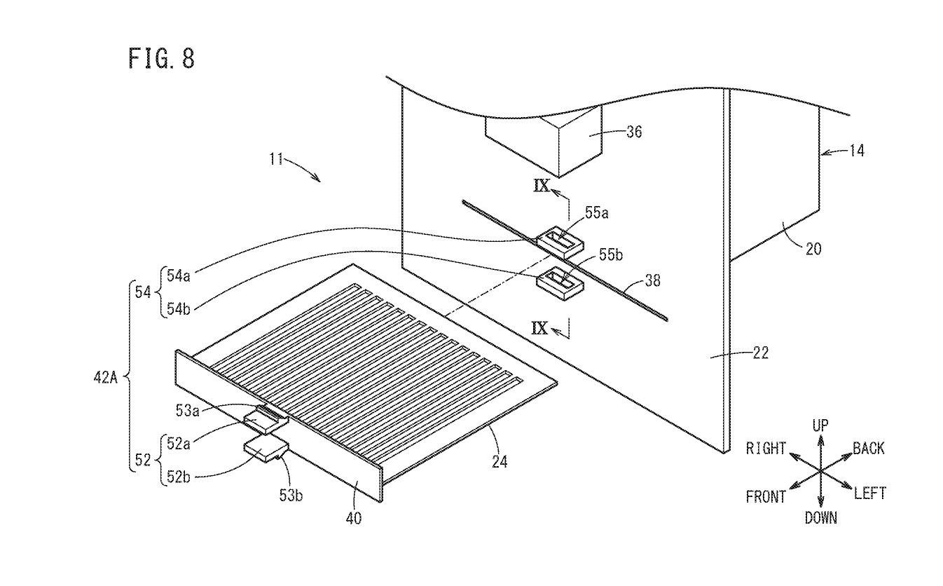

FIG. 8 in a state where the fixing member according to the third modification is used to attach the filter plate to the heatsink main body;

FIG. 10 is a view for explaining a method for fixing the filter plate to a flange portion of a flange by using a pressing plate according to a fourth modification; and

FIG. 11 is a view of the heatsink main body and the filter plate, showing a shape of the filter plate according to a fifth modification, viewed from front.

### DESCRIPTION OF THE PREFERRED EMBODIMENTS

A preferred embodiment of a heatsink and a motor driving device according to the present invention will be described in detail below with reference to the accompanying drawings.

### First Embodiment

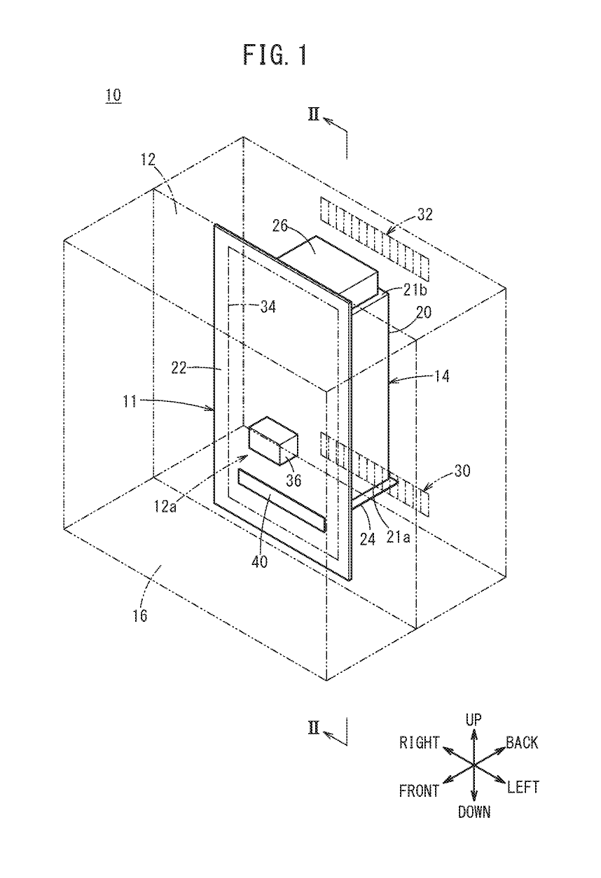

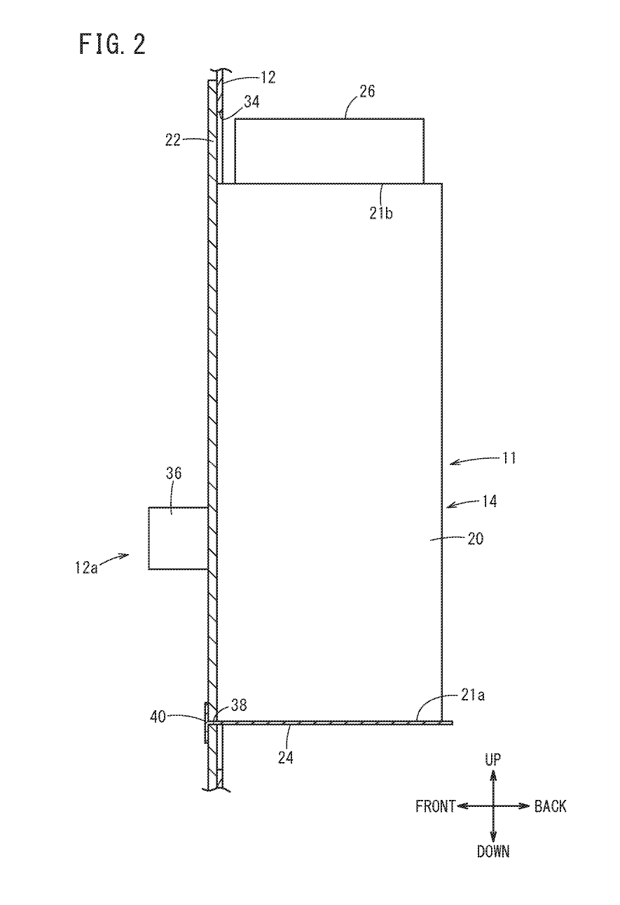

FIG. 1 is an external appearance perspective view showing a configuration of a control panel 10. FIG. 2 is a partial cross-sectional view along a line II-II in FIG. 1. Directions of front, back, left, right, up and down will be described below based on the arrows shown in FIG. 1.

A housing 16 of the control panel 10 includes inside a motor driving device 11 that includes an electronic part 12a and a heatsink 14 that cools the electronic part 12a, and a mounting panel 12 on which the motor driving device 11 is mounted.

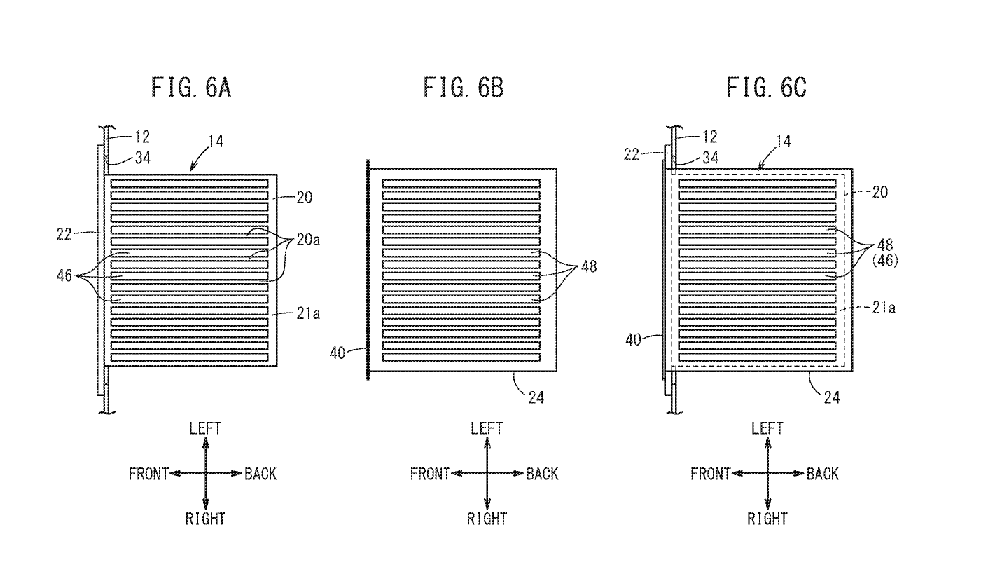

The heatsink 14 includes a heatsink main body 20 that includes a plurality of fins 20a (see FIG. 6A), a flange portion 22 that is formed on a side surface of the heatsink main body 20, and a filter plate 24 that is detachably attached to a lower side (inlet side) of the heatsink main body 20. The filter plate 24 is preferably attached such that, when the filter plate 24 is attached to the lower side of the heatsink main body 20, the filter plate 24 is in contact with an end portion (referred to as an inlet side end portion hereinafter) 21a on the lower side of the heatsink main body 20. In the present embodiment, the filter plate 24 is attached to the heatsink main body 20 such that the filter plate 24 is in contact with the inlet side end portion 21a of the heatsink main body 20.

Although not shown, in general, an openable door is arranged on a front side of the housing 16 of the control panel 10. According to the present invention, by opening this door, an operator can perform maintenance and inspection including replacement of the filter plate 24.

A fan 26 is arranged at an end portion (referred to as an outlet side end portion below) 21b on an upper side (outlet side) of the heatsink main body 20. This fan 26 forcibly causes a fluid (a gas such as air) in the heatsink main body 20 to flow from a lower side to an upper side. The heatsink main body 20 has a substantially cuboid shape. The flange portion 22 is formed on the side surface on a front side of the heatsink main body 20. The flange portion 22 is used to attach the heatsink 14 to the mounting panel 12.

The mounting panel 12 divides (partitions) a space in the housing 16 into two spaces of front and back. The heatsink main body 20 is housed in the space on back side divided (partitioned) by the mounting panel 12. Intake ports 30 and outlet ports 32 are formed on a back side surface of the housing 16. The intake ports 30 are located lower than the inlet side end portion 21a of the heatsink main body 20. The outlet ports 32 are located higher than the outlet side end portion 21b of the heatsink main body 20. More specifically, the outlet ports 32 are located higher than the fan 26. Hence, a fluid taken in through the intake ports 30 flows from the lower side to the upper side in the heatsink main body 20, and then is discharged through the fan 26 and discharged from the outlet ports 32. The fluid flowing in through the intake ports 30 is mixed with dust or a mist working fluid.

The flange portion 22 is attached to the mounting panel 12. That is, the heatsink main body 20 is attached to the mounting panel 12 by the flange portion 22. An opening portion 34 is formed in the mounting panel 12 and allows insertion of the heatsink main body 20, the filter plate 24 and the fan 26. The flange portion 22 is attached to the mounting panel 12 in a state where the heatsink main body 20 is inserted from the front side into the opening portion 34. The flange portion 22 is attached to the mounting panel 12 in a state where a back surface of the flange portion 22 and a front surface of the mounting panel 12 are in contact. Consequently, it is possible to detach the heatsink 14 provided with the flange portion 22 by opening the door arranged on the front surface on the side of the housing 16. The opening portion 34 is smaller than the shape of the flange portion 22. The flange portion 22 does not pass through the opening portion 34.

A power device 36 that is a part of the electronic part 12a is arranged on the front surface of the flange portion 22. The power device 36 is a power semiconductor element or an intelligent power module (IPM) of an insulated gate bipolar transistor (IGBT), a thyristor, a rectifier diode or a power transistor (power MOSFET). Thus, by attaching the power device 36 having a high heat generation to the flange portion 22 or to the heatsink main body 20 through an opening formed in the flange portion 22, it is possible to cool the power device 36.

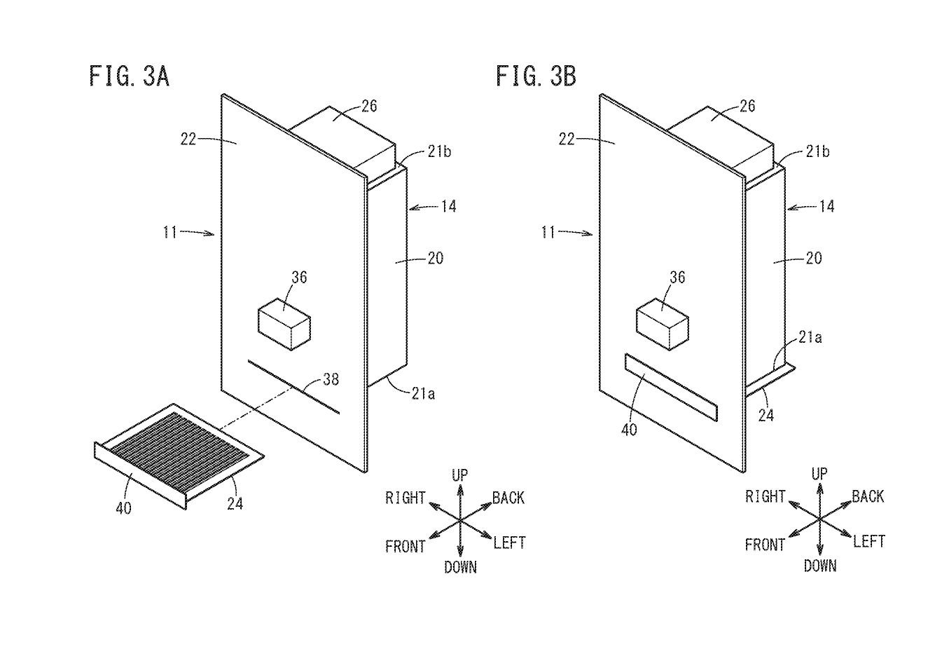

FIG. 3A is an external appearance perspective view of the heatsink 14 shown in FIG. 1 in a state before the filter plate 24 is attached to the inlet side end portion 21a of the heatsink main body 20. FIG. 3B is an external appearance perspective view of the heatsink 14 shown in FIG. 1 in a state after the filter plate 24 is attached to the inlet side end portion 21a of the heatsink main body 20.

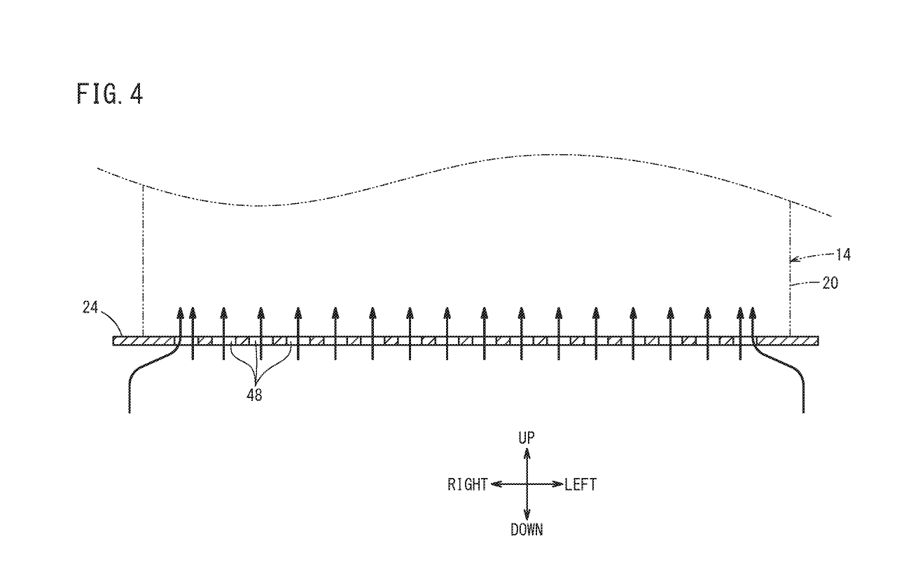

The filter plate 24 is formed such that, when the filter plate 24 is attached to the inlet side end portion 21a of the heatsink main body 20, the outer shape of the filter plate 24 is larger than the outer shape of the inlet side end portion 21a of the heatsink main body 20 on a plane perpendicular to a flow direction (upper and lower directions) of the fluid in the heatsink main body 20. Consequently, as shown in FIG. 4, it is possible to cause the fluid flowing from the lower side to the upper side to flow in the heatsink main body 20 in a range larger than the area of the inlet side end portion 21a of the heatsink main body 20. Consequently, it is possible to increase the amount of the fluid flowing in the heatsink main body 20, and improve cooling performance. FIG. 4 is a view of the heatsink main body 20 and the filter plate 24 from, showing a flow of the fluid flowing in the heatsink main body 20, viewed from front with the flange portion 22 and a flange 40 omitted.

An insertion hole 38 is formed in the flange portion 22, and allows insertion of the filter plate 24 to attach the filter plate 24 from the front side to the inlet side end portion 21a of the heatsink main body 20. Consequently, by inserting the filter plate 24 from the front side of the flange portion 22 into the insertion hole 38, the operator can easily attach the filter plate 24 to the inlet side end portion 21a of the heatsink main body 20.

The flange 40 is formed at the front end portion of the filter plate 24 (an end portion on a side opposite to the forefront end in an insertion direction of the filter plate 24 into the insertion hole 38). This flange 40 is used to position the filter plate 24 with respect to the heatsink main body 20. When the flange 40 of this filter plate 24 and the flange portion 22 come into contact, the filter plate 24 is positioned.

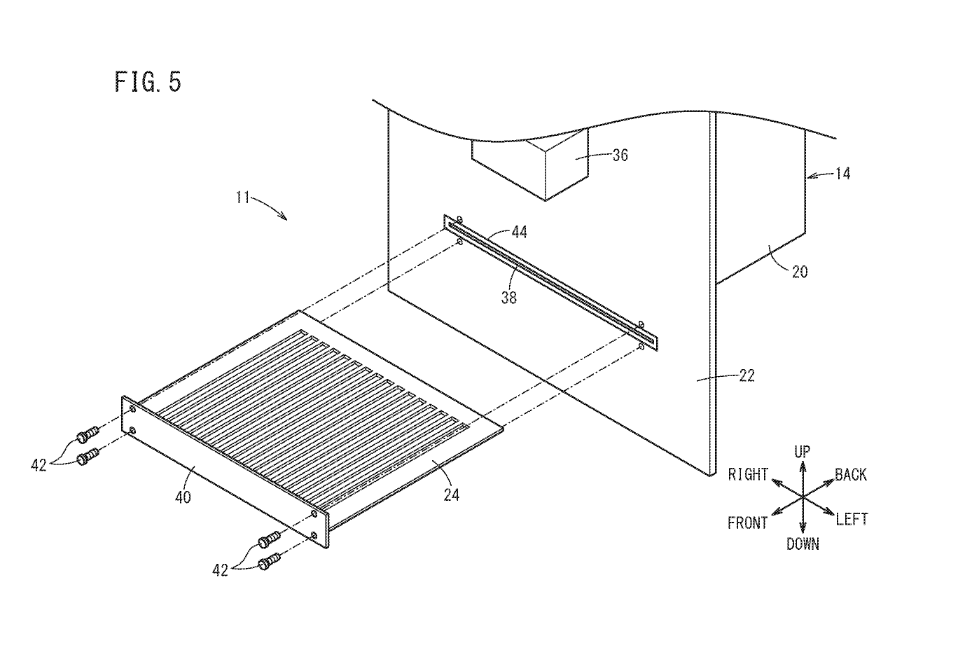

As shown in FIG. 5, the flange 40 formed on the filter plate 24 is fixed to the flange portion 22 by fixing members (screws) 42. Consequently, it is possible to fix the filter plate 24 to the heatsink main body 20. A seal member 44 such as a gasket may be arranged between the flange 40 and the flange portion 22. When the seal member 44 is provided, the flange 40 and the flange portion 22 come into contact with the seal member 44 interposed therebetween. Consequently, it is possible to keep the flange 40 in tight contact with the flange portion 22. The fluid in the back side space of the housing 16 divided by the mounting panel 12, i.e., a fluid in the space in which the heatsink main body 20 is arranged can be prevented from passing through the insertion hole 38 to the front side space of the housing 16 divided by the mounting panel 12.

FIG. 6A is a view showing the inlet side end portion 21a of the heatsink main body 20 from below. FIG. 6B is a view showing the filter plate 24 from below. FIG. 6C is a view showing the filter plate 24 attached to the inlet side end portion 21a of the heatsink main body 20 from below.

In the heatsink main body 20, the plurality of fins 20a form a plurality of flow paths 46 in which the fluid having flowed from the lower side into the heatsink main body 20 flows upward (see FIG. 6A). A plurality of vent holes 48 are formed in the filter plate 24, and cause the fluid to flow toward the inlet side of the heatsink main body 20 (see FIG. 6B). In a state where the filter plate 24 is attached to the inlet side end portion 21a of the heatsink main body 20, the shapes of the plurality of flow paths 46 at the inlet side end portion 21a of the heatsink main body 20, and the shapes of the plurality of vent holes 48 of the filter plate 24 match. Consequently, when the fluid including the dust or the mist working fluid flows in the heatsink main body 20 via the filter plate 24, the dust or the working fluid adheres to the filter plate 24. Then, it is possible to prevent the dust or the working fluid from adhering to the inlet side end portion 21a of the heatsink main body 20.

FIG. 6C shows an example where the shapes of the plurality of flow paths 46 at the inlet side end portion 21a of the heatsink main body 20 and the shapes of the plurality of vent holes 48 of the filter plate 24 completely match. However, these shapes may not perfectly match and only need to match within a predetermined allowable range.

### MODIFICATIONS

The embodiment may be modified as follows. In the following modification, the same components as those in the embodiment will be assigned by the same reference numerals, and only differences will be described.

### First Modification

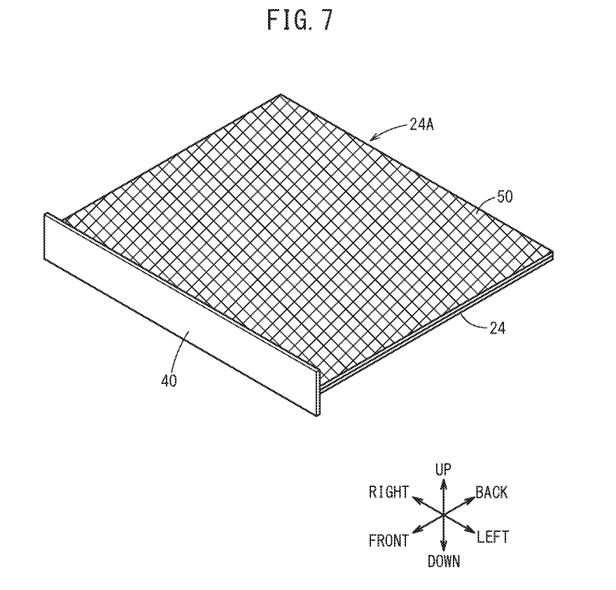

FIG. 7 is a perspective view showing a configuration of a filter plate 24A according to the first modification. The filter plate 24A is formed by arranging an air filter 50 on the filter plate 24 described in the embodiment. The air filter 50 may be arranged on a fluid downstream side (a side of the heatsink main body 20) of the filter plate 24A or may be arranged on a fluid upstream side (a side opposite to the side of the heatsink main body 20) of the filter plate 24A.

When the air filter 50 is not arranged, the fluid having passed through the vent holes 48 of the filter plate 24 include the dust or the mist working fluid. Therefore, the dust or the working fluid adheres to the interior of the heatsink main body 20 and the fan 26. However, according to the first modification, by using the filter plate 24A including the air filter 50, it is possible to prevent the dust or the working fluid from adhering to the heatsink main body 20 and the fan 26.

The plurality of vent holes 48 may be not formed in the filter plate 24A unlike the filter plate 24 according to the embodiment. In this case, one large vent hole may be formed in the filter plate 24A, and the air filter 50 may be arranged covering this one vent hole.

### Second Modification

According to the embodiment and the first modification, the fan 26 is arranged at the outlet side end portion 21b of the heatsink main body 20. However, the fan 26 may not be arranged. In this case, the opening portion 34 may have a size that allows insertion of the heatsink main body 20 and the filter plate 24.

### Third Modification

According to the embodiment and the first and second modifications, the screws are used as the fixing members 42 to fix the flange 40 of the filter plate 24 to the flange portion 22. However, according to the third modification, a fixing member 42A other than the screws is used to fix the flange 40 to the flange portion 22.

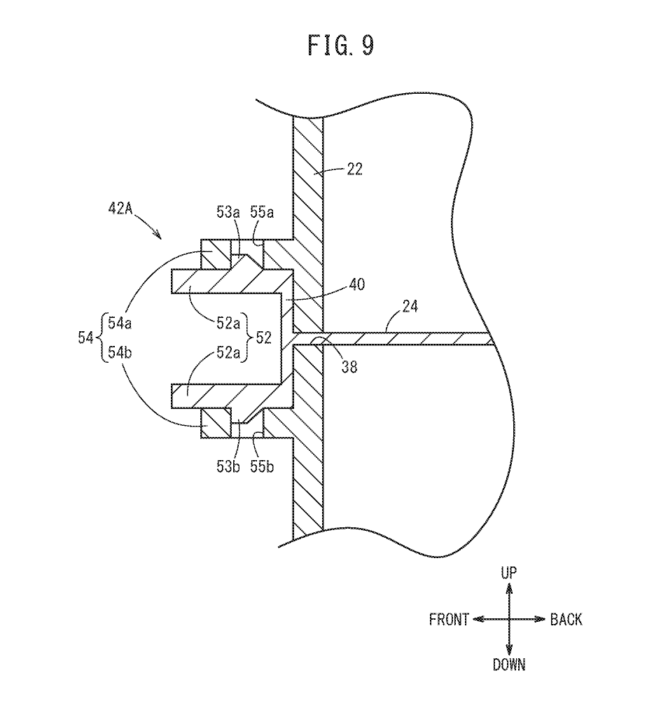

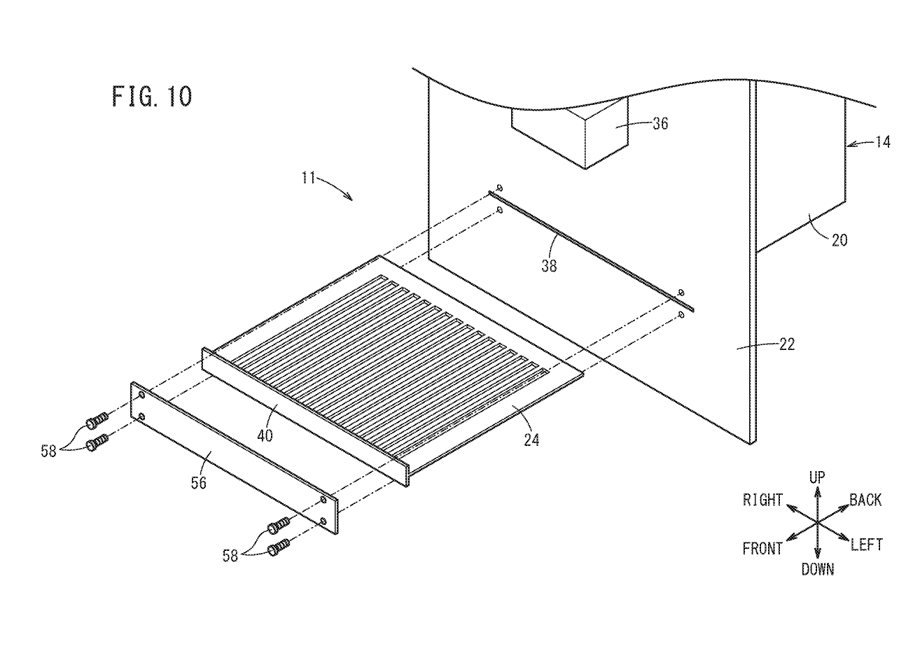

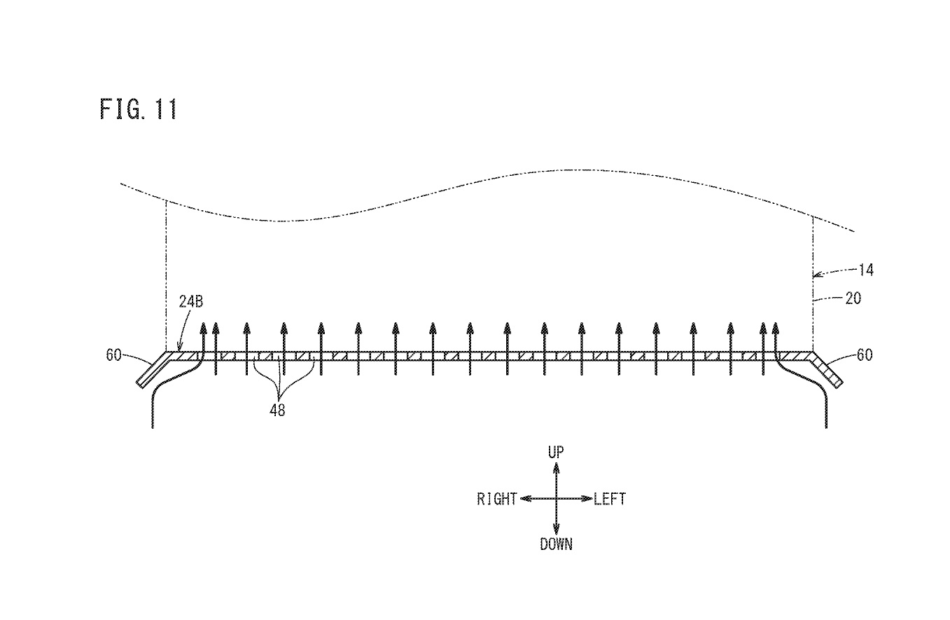

FIG. 8 is a view showing a configuration of the fixing member 42A according to the third modification. FIG. 9 is a cross-sectional view along a line IX-IX in FIG. 8 when the fixing member 42A is used to fix the filter plate 24 to the heatsink main body 20. The flange 40 of the filter plate 24 is provided with a first engagement portion 52 that constitutes a part of the fixing member 42A. The flange portion 22 is provided with a second engagement portion 54 that constitutes a part of the fixing member 42A and engages with the first engagement portion 52.

The first engagement portion 52 includes two extended members 52a, 52b extending forward from the front surface of the flange 40 at the center in the left and right directions of the flange 40. The extended member 52a is formed at an upper end portion of the flange 40. The extended member 52b is formed at a lower end portion of the flange 40.

The second engagement portion 54 includes two extended members 54a, 54b extending forward form the front surface of the flange portion 22 at the center in the left and right directions of the insertion hole 38. When the filter plate 24 is attached to the inlet side of the heatsink main body 20, the extended member 54a is arranged above the extended member 52a, and the extended member 54b is arranged below the extended member 52b.

The extended member 52a is provided with a protrusion portion 53a protruding upward from an upper surface. The extended member 52b is provided with a protrusion portion 53b protruding downward from a lower surface. The extended member 54a is provided with a through-hole 55a in which the protrusion portion 53a is inserted and with which the protrusion portion 53a is engaged. The extended member 54b is provided with a through-hole 55b in which the protrusion portion 53b is inserted and with the protrusion portion 53b is engaged.

When the operator inserts the filter plate 24 in the insertion hole 38 formed in the flange portion 22, and the flange 40 of the filter plate 24 comes into contact with the flange portion 22, the protrusion portions 53a, 53b engage with the through-holes 55a, 55b. Consequently, it is possible to fix the filter plate 24 to the heatsink main body 20. When the filter plate 24 needs to be detached, the operator pinches the two extended members 52a, 52b by fingers to disengage the protrusion portions 53a, 53b from the through-holes 55a, 55b. Consequently, by pinching and pulling the two extended members 52a, 52b forward by the fingers, the operator can easily detach the filter plate 24 from the heatsink main body 20.

### Fourth Modification

According to the embodiment and the first to third modifications, the fixing members 42 (or 42A) are used to fix the flange 40 of the filter plate 24 to the flange portion 22. However, according to the fourth modification, a pressing plate 56 is used to fix the flange 40 of the filter plate 24 to the flange portion 22.

FIG. 10 is a view for explaining a method for fixing the flange 40 to the flange portion 22 by using the pressing plate 56. The pressing plate 56 presses the flange 40 backward from the front side of the flange 40 of the filter plate 24. Thus, the flange 40 of the filter plate 24 is pressed toward the flange portion 22 by the pressing plate 56, and is fixed to the flange portion 22. The means for pressing the flange 40 by using this pressing plate 56 fixes the pressing plate 56 to the flange portion 22 by fixing members 58 such as screws to press the flange 40 toward the flange portion 22.

The pressing plate 56 may be a member used to fix another member. In this case, as the other member is fixed, the pressing plate 56 presses the flange 40 of the filter plate 24 toward the flange portion 22.

### Fifth Modification

FIG. 11 is a view showing a shape of a filter plate 24B according to the fifth modification, and is a view showing the heatsink main body 20 and the filter plate 24B from front. FIG. 11 does not show the flange portion 22 and the flange 40.

Except that end portions of the filter plate 24B are diagonally bent toward the upstream side of the fluid flowing in the heatsink main body 20, the filter plate 24B is the same as the filter plate 24 described in the embodiment. That is, bent portions (portions that are bent) 60 are formed at the end portions of the filter plate 24B. The end portions of this filter plate 24B are portions that, in a state where the filter plate 24B is attached to the inlet side end portion 21a of the heatsink main body 20, protrude from the outer shape of the heatsink main body 20 on a plane perpendicular to the flow direction (upper and lower directions) of the fluid in the heatsink main body 20. The vent holes 48 are not formed at the bent portions 60 of this filter plate 24B.

Consequently, by using the filter plate 24B, it is possible to smoothly guide the fluid flowing from the lower side to the upper side into the heatsink main body 20 in the wider range than the area of the heatsink main body 20. It is possible to further increase the amount of the fluid flowing in the heatsink main body 20 so as to further improve the cooling performance. The fifth modification and at least one of the first to fourth modifications may be arbitrarily combined.

### Technical Idea Obtained from Embodiment

The technical idea that can be learned from the embodiment and the first to fifth modifications will be described below.

A heatsink (14) configured to cool an electronic part (12a) includes a heatsink main body (20) including a plurality of fins (20a); a flange portion (22) formed on the heatsink main body (20) to install the heatsink (14) with the electronic part (12a) mounted thereon; and a filter plate (24, 24A, 24B) detachably attached to an end portion (21a) on an inlet side of the heatsink main body (20). In a state where the filter plate (24, 24A, 24B) is attached to the end portion (21a) on the inlet side of the heatsink main body (20), an outer shape of the filter plate (24, 24A, 24B) is larger than an outer shape of the end portion (21a) on the inlet side of the heatsink main body (20) on a plane perpendicular to a flow direction of a fluid in the heatsink main body (20). An insertion hole (38) formed in the flange portion (22) allows the filter plate (24, 24A, 24B) to be inserted to attach the filter plate (24, 24A, 24B) from a side of the flange portion (22) to the end portion (21a) on the inlet side of the heatsink main body (20). A flange (40) is formed on the filter plate (24, 24A, 24B) at an end portion on a side opposite to a forefront end of the filter plate (24, 24A, 24B) in an insertion direction of the filter plate (24, 24A, 24B) into the insertion hole (38) for positioning of the filter plate (24, 24A, 24B) with respect to the heatsink main body (20).

With this simple configuration, it is possible to position the filter plate (24) with respect to the end portion (21a) on the inlet side of the heatsink main body (20). Further, it is possible to increase the amount of the fluid flowing in the heatsink main body (20), improving the cooling performance.

A plurality of flow paths (46) may be formed by the plurality of fins (20a) guide the fluid having flowed into the heatsink main body (20) from the end portion (21a) on the inlet side of the heatsink main body (20) to flow toward an outlet side. A plurality of vent holes (48) may be formed in the filter plate (24, 24A, 24B). In a state where the filter plate (24, 24A, 24B) is attached to the end portion (21a) on the inlet side of the heatsink main body (20), shapes of the plurality of vent holes (48) of the filter plate (24, 24A, 24B) and shapes of the plurality of flow paths (46) at the end portion on the inlet side of the heatsink main body (20) may match within a predetermined allowable range on the plane perpendicular to the flow direction of the fluid in the heatsink main body (20). Consequently, it is possible to prevent adhesion of dust or a working fluid to the end portion (21a) on the inlet side of the heatsink main body (20).

The filter plate (24A) may include an air filter (50). Consequently, it is possible to further prevent the adhesion of the dust or the working fluid to the heatsink main body (20).

The flange (40) of the filter plate (24, 24A, 24B) may be fixed to the flange portion (22) by a fixing member (42, 42A) in a state where the filter plate (24, 24A, 24B) is inserted in the insertion hole (38). Consequently, it is possible to easily fix the filter plate (24, 24A, 24B) to the heatsink main body (20).

The flange (40) of the filter plate (24, 24A, 24B) may be pressed toward the flange portion (22) by a pressing plate (56) and fixed to the flange portion (22) in a state where the filter plate (24, 24A, 24B) is inserted in the insertion hole (38). Consequently, it is possible to easily fix the filter plate (24, 24A, 24B) to the heatsink main body (20).

A seal member (44) may be arranged between the flange (40) of the filter plate (24, 24A, 24B) and the flange portion (22). Consequently, it is possible to keep the flange (40) in tight contact with the flange portion (22).

A bent portion (60) may be formed at an end of the filter plate (24B) diagonally toward an upstream side of the fluid flowing in the heatsink main body (20). Consequently, it is possible to further increase the amount of the fluid flowing in the heatsink main body (20), improving the cooling performance.

The end of the filter plate (24B) attached to the end portion (21a) on the inlet side of the heatsink main body (20) may protrude from the outer shape of the end portion (21a) on the inlet side of the heatsink main body (20) on the plane perpendicular to the flow direction of the fluid in the heatsink main body (20). Consequently, it is possible to further increase the amount of the fluid flowing in the heatsink main body (20), further improving the cooling performance.

A fan (26) may be arranged at an end portion (21b) on an outlet side of the heatsink main body (20).

An opening portion (34) may be formed in a mounting panel (12) to which the heatsink (14) is attached, so that the heatsink main body (20) is inserted into the opening portion (34). The flange portion (22) may be attached to the mounting panel (12) in a state where the heatsink main body (20) is inserted in the opening portion (34). Consequently, a detachment direction of the filter plate (24, 24A, 24B) from the mounting panel (12) and a detachment direction of the heatsink main body (20) from the mounting panel (12) can be made the same. Thus, it is possible to improve operability of maintenance and inspection.

A power device (36) that is a part of the electronic part (12a) may be mounted on a surface of the flange portion (22) on a side opposite to a side on which the heatsink main body (20) is arranged. By arranging the power device (36) on the flange portion (22) formed on the heatsink main body (20), it is possible to efficiently cool the power device (36) of high heat generation. Further, the operability of the maintenance and the inspection of the power device (36) improves.

A motor driving device (11) configured to drive a motor includes: the heatsink (14); and the electronic part (12a).

The simple configuration can easily position the filter plate (24) with respect to the end portion (21a) on the inlet side of the heatsink main body (20). Further, it is possible to increase the amount of the fluid flowing in the heatsink main body (20), improving the cooling performance.

Although certain preferred embodiments of the present invention have been shown and described in detail, it should be understood that various changes and modifications may be made therein without departing from the scope of the appended claims.

What is claimed is:

1. A heatsink configured to cool an electronic part, the heatsink comprising:
a heatsink main body including a plurality of fins;
a flange portion formed on the heatsink main body to install the heatsink with the electronic part mounted thereon; and
a filter plate detachably attached to an end portion on an inlet side of the heatsink main body, wherein:
in a state where the filter plate is attached to the end portion on the inlet side of the heatsink main body, an outer shape of the filter plate is larger than an outer shape of the end portion on the inlet side of the heatsink main body on a plane perpendicular to a flow direction of a fluid in the heatsink main body;
an insertion hole formed in the flange portion allows the filter plate to be inserted into the filter plate from a side of the flange portion to the end portion on the inlet side of the heatsink main body; and
a flange is formed on the filter plate at an end portion on a side opposite to a forefront end of the filter plate in an insertion direction of the filter plate into the insertion hole for positioning the filter plate with respect to the heatsink main body.

2. The heatsink according to claim 1, wherein:
a plurality of flow paths formed by the plurality of fins guide the fluid, the fluid having flowed from the end portion on the inlet side of the heatsink main body to flow toward an outlet side;
a plurality of vent holes are formed in the filter plate; and
in a state where the filter plate is attached to the end portion on the inlet side of the heatsink main body, shapes of the plurality of vent holes of the filter plate and shapes of the plurality of flow paths at the end portion on the inlet side of the heatsink main body match within a predetermined allowable range on the plane perpendicular to the flow direction of the fluid in the heatsink main body.

3. The heatsink according to claim 1, wherein the filter plate includes an air filter.

4. The heatsink according to claim 1, wherein the flange of the filter plate is fixed to the flange portion by a fixing member in a state where the filter plate is inserted in the insertion hole.

5. The heatsink according to claim 1, wherein the flange of the filter plate is pressed toward the flange portion by a pressing plate and fixed to the flange portion in a state where the filter plate is inserted in the insertion hole.

6. The heatsink according to claim 1, wherein a seal member is arranged between the flange of the filter plate and the flange portion.

7. The heatsink according to claim 1, wherein a bent portion is formed at an end portion of the filter plate diagonally toward an upstream side of the fluid flowing in the heatsink main body.

8. The heatsink according to claim 7, wherein the end portion of the filter plate attached to the end portion on the inlet side of the heatsink main body protrudes from the outer shape of the end portion on the inlet side of the heatsink main body on the plane perpendicular to the flow direction of the fluid in the heatsink main body.

9. The heatsink according to claim 1, wherein a fan is arranged at an end portion on an outlet side of the heatsink main body.

10. The heatsink according to claim 1, wherein:
an opening portion is formed in a mounting panel to which the heatsink is attached so that the heatsink main body is inserted into the opening portion; and
the flange portion is attached to the mounting panel in a state where the heatsink main body is inserted in the opening portion.

11. The heatsink according to claim 10, wherein a power device that is a part of the electronic part is mounted on a surface of the flange portion on a side opposite to a side on which the heatsink main body is arranged.

12. A motor driving device configured to drive a motor, the motor driving device comprising:
the heatsink according to claim 1; and
the electronic part.
